(19) United States
(12) Patent Application Publication
(10) Pub. No.: US 2009/0309187 A1
(43) Pub. Date: Dec. 17, 2009

(54) Semiconductor Device and Method of Fabricating the Same

(76) Inventors: Jae-hyoung Choi, Gyeonggi-do (KR); Cha-young Yoo, Gyeonggi-do (KR); Jong-cheol Lee, Seoul (KR); Kyoung-ryul Yoon, Gyeonggi-do (KR); Ki-vin Im, Gyeonggi-do (KR); Hoon-sang Choi, Seoul (KR); Se-hoon Oh, Gyeonggi-do (KR); Se-hwi Cho, Seoul (KR)

Correspondence Address: MYERS BIGEL SIBLEY & SAJOVEC, PO BOX 37428, RALEIGH, NC, 27627, US

(21) Appl. No.: 12/544,500

(22) Filed: Aug. 20, 2009

Related U.S. Application Data
(63) Continuation-in-part of application No. 11/210,332, filed on Aug. 24, 2005.

(30) Foreign Application Priority Data
Jul. 8, 2009 (KR) 2009-62221

(51) Int. Cl. H01L 29/92; H01G 4/06

(52) U.S. Cl. 257/532; 361/313; 257/296; 257/E29.342

(57) ABSTRACT

Provided is a semiconductor device including a multi-layer dielectric structure and a method of fabricating the semiconductor device. According to one example embodiment, the semiconductor device includes a capacitor comprising: first and second electrodes facing each other; at least one first dielectric layer that is disposed between the first and second electrodes, the at least one first dielectric layer comprising a first high-k dielectric layer doped with silicon; and at least one second dielectric layer that is disposed between the at least one first dielectric layer and any of the first and second electrodes, the at least one second dielectric layer having a higher crystallization temperature than that of the first dielectric layer.

### REFERENCE TO PRIORITY APPLICATIONS

This application is a continuation-in-part application of prior application Ser. No. 11/210,332, filed Aug. 24, 2005, which claims the benefit of Korean Patent Application 10-2004-0067433, and claims priority to Korean Patent Application No. 10-2009-0062221, filed Jul. 8, 2009, the disclosures of which are hereby incorporated herein by reference.

### BACKGROUND

The present disclosure relates to a semiconductor device and a method of fabricating the semiconductor device, and more particularly, to a semiconductor device having a capacitor including a multi-layer dielectric structure and a method of fabricating the semiconductor device.

Large-scale integrated (LSI) circuits known as semiconductor devices can be generally classified into memory devices and logic devices. Advances in the semiconductor industry have allowed rapid increase in the integration density of the memory devices and these advances now result in implementing a design rule of 30 nm or less on the memory devices.

A dynamic random access memory (DRAM) is a type of the memory device. A memory cell of the DRAM comprises a field effect transistor serving as an access device, and a capacitor for storing data. As the scale of DRAM has been continuously decreased, the area occupied by the capacitor in the memory cell has been continuously decreased. To ensure sufficient effective capacity despite the reduction of the area, there are many researches in progress, and recently, a technique of using a high-k dielectric material with a high dielectric constant of 15 or greater for a dielectric layer of the capacitor become one main technique.

Conventionally, metal oxide materials such as hafnium oxide, zirconium oxide, or lanthanum oxide have been suggested for the high-k dielectric material. However, these metal oxide materials have a challenge to be applied for the dielectric layers due to their relatively high leakage current. In particular, when a capacitor in which such metal oxide materials are used for a dielectric layer, is subjected to subsequent back-end processes having a high thermal budget, for example, formation processes of dielectric inter-layer or interconnection components, leakage current and bit errors generally increase, resulting in drastic reduction of electrical reliability or the capacitor. The leakage current and bit errors occur more frequently in a DRAM having three-dimensional storage nodes than in a DRAM having planar storage nodes.

### SUMMARY

Exemplary embodiments of the present invention may provide a highly reliable semiconductor device in that a dielectric layer has strong resistance to high temperature back-end processes, whereby reducing or preventing leakage current and bit errors.

Exemplary embodiments of the present invention may also provide a method of manufacturing a semiconductor device having the above-described features and advantages.

According to an aspect of the inventive concept, there is provided a semiconductor device comprising a capacitor, the capacitor comprising: first and second electrodes facing each other; at least one first dielectric layer that is disposed between the first and second electrodes, the at least one first dielectric layer comprising a first high-k dielectric layer doped with silicon; and at least one second dielectric layer that is disposed between the at least one first dielectric layer and any of the first and second electrodes, the at least one second dielectric layer having a higher crystallization temperature than that of the first dielectric layer.

At least one of the first and second electrodes may comprise at least one of the group consisting of a titanium nitride layer, a tantalum nitride layer, and a tungsten nitride layer. The first and second electrodes may be a bottom electrode and a top electrode of the capacitor, respectively, and the at least one second dielectric layer may be disposed between the at least one first dielectric layer and the second electrode.

The first high-k dielectric layer may comprise one selected from the group consisting of a zirconium oxide layer (ZrOₓ), a hafnium oxide layer (HfOₓ), a lanthanum oxide layer (LaOₓ), and a combination thereof. The at least one second dielectric layer may comprise one selected from the group consisting of an aluminum oxide layer (AlOₓ), an aluminum nitride layer (AlNₓ), and a combination thereof.

The semiconductor device may further comprise at least one third dielectric layer disposed between the at least one second dielectric layer and the other of the first and second electrodes, wherein the at least one third dielectric layer comprises a second high-k dielectric layer. The second high-k dielectric layer may comprise one selected from the group consisting of a zirconium oxide layer (ZrOₓ), a hafnium oxide layer (HfOₓ), a lanthanum oxide layer (LaOₓ), and a combination thereof. The second high-k dielectric layer may be doped with silicon.

The first and second electrodes may be a bottom electrode and a top electrode of the capacitor, respectively, and the at least one second dielectric layer may be disposed between the at least one first dielectric layer and the second electrode, and the at least one third dielectric layer may be disposed between the at least one second dielectric layer and the second electrode, and the thickness of the at least one first dielectric layer may be greater than that of the at least one third dielectric layer.

The thickness of the at least one second dielectric layer may be less than that of the at least one first dielectric layer. The thickness of the at least one second dielectric layer may be 1 to 20 Å. The thickness of the at least one first dielectric layer may be 40 to 100 Å.

According to another aspect of the inventive concept, there is provided a method of fabricating a semiconductor device, the method comprising: providing a substrate in a reactor: forming a first conductive layer to be a first electrode, on the substrate: forming at least one first dielectric layer including a first high-k dielectric layer doped with silicon, on the conductive layer to be a first electrode; forming at least one second dielectric layer having a higher crystallization temperature than that of the first dielectric layer, on the first dielectric layer; and forming a second conductive layer to be a second electrode, on the second dielectric layer.

The forming of the at least one first dielectric layer may be performed by chemical vapor deposition (CVD) or atomic layer deposition (ALD). The ALD may be conducted by performing, at least once, a cycle including a silicon precursor pulse/oxidizing agent pulse/metal precursor pulse/oxidizing agent pulse or including a metal precursor pulse/oxidizing agent pulse silicon precursor pulse/oxidizing agent pulse. Alternatively, the ALD may be conducted by performing, at least once, an ALD cycle including a silicon precursor pulse/metal precursor pulse/oxidizing agent pulse or including an oxidizing agent pulse/silicon precursor pulse/metal precursor pulse.

At least one of the first and second conductive layers may comprise at least one of the group consisting of a titanium nitride layer, a tantalum nitride layer, and a tungsten nitride layer. The first high-k dielectric layer may comprise one of the group consisting of a zirconium oxide layer (ZrOₓ), a hafnium oxide layer (HfOₓ), a lanthanum oxide layer (LaOₓ), and a combination thereof. Also, the second dielectric layer may comprise one of the group consisting of an aluminum oxide layer (AlOₓ), an aluminum nitride layer (AlNₓ), and a combination thereof.

Prior to the forming of the second conductive layer, the method may further comprise forming a third dielectric layer including a second high-k dielectric layer on the second dielectric layer. In this case, the second high-k dielectric layer may comprise one of the group consisting of a zirconium oxide layer (ZrOₓ), a hafnium oxide layer (HfOₓ), a lanthanum oxide layer (LaOₓ), and a combination thereof.

According to the semiconductor device of the inventive concept, a dielectric layer having resistance to heat is provided by a multi-layer dielectric structure having a first dielectric layer including a high-k dielectric layer doped with silicon and a second dielectric layer having a higher crystallization temperature than the first dielectric layer. Accordingly, a semiconductor device which has excellent leakage current characteristics and a low bit error rate is provided, even if a high temperature post-process such as a high temperature back-end process is performed. Also, a method of manufacturing a semiconductor device having the above-described features is provided.

### BRIEF DESCRIPTION OF THE DRAWINGS

Exemplary embodiments of the present invention can be understood in more detail from the following description taken in conjunction with the accompanying drawings in which:

FIG. 1 is a cross-sectional view of a semiconductor device including multi-layer dielectric structure of ZrSiO/AlO according to an exemplary embodiment of the present invention:

FIGS. 2A and 2B are graphs showing leakage currents and percentages of bit error of capacitors including the multi-layer dielectric structure of ZrSiO/AlO according to an example embodiment of the present invention and capacitors including a ZrSiO dielectric layer for a comparison with the ZrSiO/AlO;

FIG. 3 is a cross-sectional view of a semiconductor device including a multi-layer dielectric structure according to another embodiment of the present invention:

FIGS. 4A and 4B are graphs showing respective leakage current and ratio of bit error of capacitors including the multi-layer dielectric structure of ZrSiO/AlO/ZrO according to an example embodiment of the present invention and capacitors including a multi-layer dielectric structure of ZrO/AlO/ZrO for a comparison with the ZrSiO/AlO/ZrO; and

FIGS. 5A through 5F are cross-sectional views illustrating processes of fabricating a semiconductor device according to another example embodiment of the present invention.

### DETAILED DESCRIPTION OF THE EMBODIMENTS

Example embodiments of the present invention will be described more fully with reference to the accompanying drawings.

The example embodiments will now be described more fully with reference to the accompanying drawings. The present invention may, however, be embodied in many different forms and should not be construed as being limited to the exemplary embodiments set forth herein. Like reference numerals refer to like elements.

It will be understood that when an element is referred to as being “on” another element, it can be directly on the other element or intervening elements may be present there between. In contrast, when an element is referred to as being “directly on” another element, there are no intervening elements present. As used herein, the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the example embodiment.

Hereinafter, exemplary embodiments of the present invention will be described with reference to accompanying drawings schematically illustrating the embodiments. In the drawings, for example, illustrated shapes may be deformed according to fabrication technology and/or tolerances. Therefore, the exemplary embodiments of the present invention are not limited to certain shapes illustrated in the present specification, and may include modifications of shapes caused in fabrication processes.

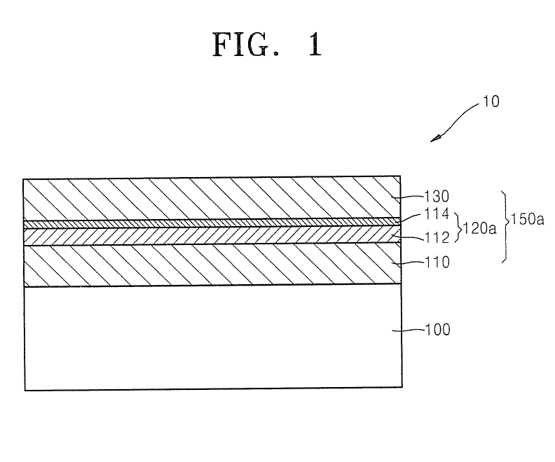

FIG. 1 is a cross-sectional view of a semiconductor device 10 having a capacitor 150a including a multi-layer dielectric structure 120a according to an example embodiment of the present invention.

Referring to FIG. 1, the semiconductor device 10 includes a stacked capacitor 150a formed on a substrate 100. The capacitor 150a may include first and second electrodes 110 and 130 facing each other, and a multi-layer dielectric structure 120a disposed between the first and second electrodes 110 and 130.

Although not illustrated in FIG. 1, an access device for driving the stacked capacitor 150a may be formed on the substrate 100. The access device may be, for example, a field effect transistor that is connected to the first electrode 110, for implementing a 1T-1C memory cell. In the field effect transistor, the length and the shape of a channel, or the shape and the concentration of impurity regions may be appropriately selected to prevent or reduce a short channel effect (SCE) and leakage current. However, the access device is not limited to the field effect transistor. For example, the access device may be formed of two or more coupled transistors that operate in a non-destructive read mode. Also, the access device may be, for example, a graphene or a nano switching device.

As illustrated in FIG. 1, the first and second electrodes 110 and 130 may be a bottom electrode and a top electrode of the capacitor 150a, respectively. The first and second electrodes 110 and 130 may be formed by forming a conductive layer using physical vapor deposition (PVD), chemical vapor deposition (CVD), atomic layer deposition (ALD), or sequential flow deposition (SFD). A metal having a high work function, such as ruthenium (Ru), may be used for the conductive layer for forming the electrodes 110 and 130 in order to reduce or prevent a leakage current through multi-layer dielectric structure 120a. However, since the ruthenium is a noble metal, incurring high manufacturing costs, the ruthenium has a challenge to be applied for the electrodes 110 and 130. Thus, instead of the ruthenium, a refractory metal such as titanium, tantalum, tungsten, or the like or a conductive nitride thereof may be preferred for forming the electrodes 110 and 130 in economic view.

According to some example embodiments of the present invention, at least one of the first and second electrodes 110 and 130 may include one selected from the group consisting of titanium, tantalum, tungsten, and conductive nitrides thereof, and any combination thereof. As will be described later, though the above-described materials such as titanium, tantalum, tungsten, or the like or a conductive nitride thereof are used for the electrodes 110 and 130, excellent leakage current characteristics may be obtained and bit errors may be also prevented or reduced, according to an example embodiment of the present invention.

As illustrated in FIG. 1, the multi-layer dielectric layer structure 120a of the capacitor 150a may include a first dielectric layer 112 between the first electrode 110 and the second electrode 130. The first dielectric layer 112 may include a first high-k dielectric layer doped with silicon. The first high-k dielectric layer may include a zirconium oxide layer (ZrOₓ), a hafnium oxide layer (HfOₓ), a lanthanum oxide layer (LaOₓ), or a tantalum oxide layer (TaOₓ) or a combination thereof, which may have a high permittivity of more than 20.

The first dielectric layer 112 may be represented by a chemical formula, MₓSi_{y}O₇, where M is one of the group consisting of Zr, Hf, La and Ta, and x, y, and z are numbers greater than 0. The doped Si atoms may be incorporated into the metal oxide layer substitutionally and/or interstitially. According to an embodiment of the present invention, x, y, and z may each be equal to or near stoichiometric composition ratio of the compound MₓSi_{y}O_{z}, more specifically, x+y may be equal to 1. The thickness of the first dielectric layer 112 may be about 40 to 100 Å so that the first dielectric layer 112 may have equivalent oxide thickness (EOT) of about 25 Å or less.

The first dielectric layer 112 may be formed by CVD or ALD, preferably by ALD by which a thin film can be formed by unit of molecular layer on a substrate due to a self-saturating chemical reaction. The ALD process for forming the first dielectric layer of MₓSi_{y}O_{z} 112 may be performed by alternately forming a layer of silicon oxide (e.g., SiO, SiO₂, etc.) and a layer of the metal oxide.

For example, a ZrₓSi_{y}O_{z} layer may be formed by alternately stacking a layer of silicon oxide and a layer of zirconium oxide a plurality of times during the ALD process. That is, the ZrₓSi_{y}O_{z} layer may be grown by a cycle including a silicon precursor pulse/an oxidizing agent pulse/a zirconium precursor pulse/an oxidizing agent pulse. In an example embodiment, each of the pulses may be separated by a purge step. After each pulse step, if there are excess reactants and/or reaction byproducts in a reactor, they may be removed from the reactor by the purge step.

The cycle including the pulses, the purge steps or combination thereof may be repeated by a predetermined number of times in order to control the thickness and composition ratio of the first dielectric layer 112. For example, in order to obtain the first dielectric layer 112 which is a silicon rich metal oxide layer, a sequence including a silicon precursor pulse/an oxidizing agent pulse may be performed one or more times than a sequence including a metal precursor pulse/an oxidizing agent pulse.

The silicon precursor may be a silicon halide such as a silicon fluoride (e.g., SiF₄), a silicon chloride (e.g., SiCl₄), a silicon bromide (e.g., SiBr₄), or a silicon iodide (e.g., SiI₄). Similarly, the zirconium precursor may also be a zirconium halide. An example of the zirconium precursor compound may be ZrCl₄.

The oxidizing agent may be oxygen (O₂) or ozone (O₃). In other example embodiment, the oxidizing agent may be H₂O, H₂O₂, or NO or an alcohol such as isopropyl alcohol, methanol, or ethanol, which contain oxygen.

However, the above-described ALD is merely exemplary, and the present invention is not limited thereto. For example, a cycle including a silicon precursor pulse and a metal precursor pulse may be modified by considering that the silicon precursor and the metal precursor may have difference in the degree to which they are adhered to surfaces within a predetermined period of time due to their different steric constraints.

In general, it is more difficult to form a mono layer by a silicon precursor pulse than by a metal precursor pulse. Thus, it is possible to form a metal layer in available sites on an under layer which are not occupied by silicon atoms derived from the silicon precursor during a predetermined time. As a result, the first dielectric layer 112 formed of a metal oxide doped with silicon may also be formed by a cycle which is not required to have an oxidizing agent pulse between a silicon precursor pulse and a metal precursor pulse, for example, an oxidizing agent pulse/a silicon precursor pulse/a metal precursor pulse.

Likewise, when the pulses are separated by purge steps and excess reactants and/or reaction byproducts may exist after each pulse, the excess reactants and/or the reaction byproducts may be removed from the reactor by the purge step. It will be understood by one of ordinary skill in the art that the sequence of the pulses may be modified according to the thickness and composition ratio of the first dielectric layer 112.

The composition ratio of the first dielectric layer 112 may be determined by dividing the total number of metal atoms M by the sum of the metal atoms M and silicon atoms Si of the MₓSi_{y}O_{z}. The composition ratio may be determined as an average value throughout the first dielectric layer 112.

The multi-layer dielectric structure 120a may further include at least one second dielectric layer 114 that is disposed between the first dielectric layer 112 and any of the first and second electrodes 110 and 130. As illustrated in FIG. 1, the second dielectric layer 114 may be disposed between the first dielectric layer 112 and the second electrode 130 which is a top electrode for the capacitor 150a. The second dielectric layer 114 has a higher crystallization temperature than that of the first dielectric layer 112. For example, when the first dielectric layer 112 is a zirconium oxide layer (ZrOₓ), a hafnium oxide layer (HfOₓ), or a lanthanum oxide layer (LaOₓ), an aluminum oxide layer (AlOₓ) or an aluminum nitride layer (AlNₓ) having a crystallization temperature of about 850° C. may be used as the second dielectric layer 114.

The aluminum oxide layer or the aluminum nitride layer used for the second dielectric layer 114 has a wide band gap and thus may have an advantage to reduce a leakage current of the first dielectric layer 112. However, since the second dielectric layer 114 has a smaller dielectric constant than that of the first dielectric layer 112, the thickness of the second dielectric layer 114 may be limited. According to an example embodiment of the present invention, the thickness of the second dielectric layer 114 may be less than that of the first dielectric layer 112. For example, the thickness of the second dielectric layer 114 may be about 1 to about 20 Å.

It has been found from the experimental result that the second dielectric layer 114 may be highly likely to have an amorphous structure within the above thickness range and the second dielectric layer 114 may not be easily crystallized during a back-end process. Thus, it can be expected that excessive grain growth of the first dielectric layer 112 which frequently occur during the back-end process may be prevented or reduced when the second dielectric layer 114 has a thickness of about 1 to about 20 Å and, thus, a leakage current path provided by grain boundaries of the first dielectric layer 112 may be minimized.

Similar to the first dielectric layer 112, the second dielectric layer 114 may also be formed by CVD or ALD, preferably by ALD. A cycle of the ALD process for forming the second dielectric layer 114 may include a sequence of a metal precursor pulse/an oxidizing agent pulse.

In some example embodiments, the pulses may be separated by a purge step, and excess reactants and/or reaction byproducts existing after each pulse may be removed by the purge step. In other example embodiment, a cycle for the ALD process for forming the second dielectric layer 114 may include a sequence of an oxidizing agent pulse/metal precursor pulse. Then, the second electrode 130 may be formed on the second dielectric layer 114 to complete the capacitor 150a having the multi layer dielectric structure 120a.

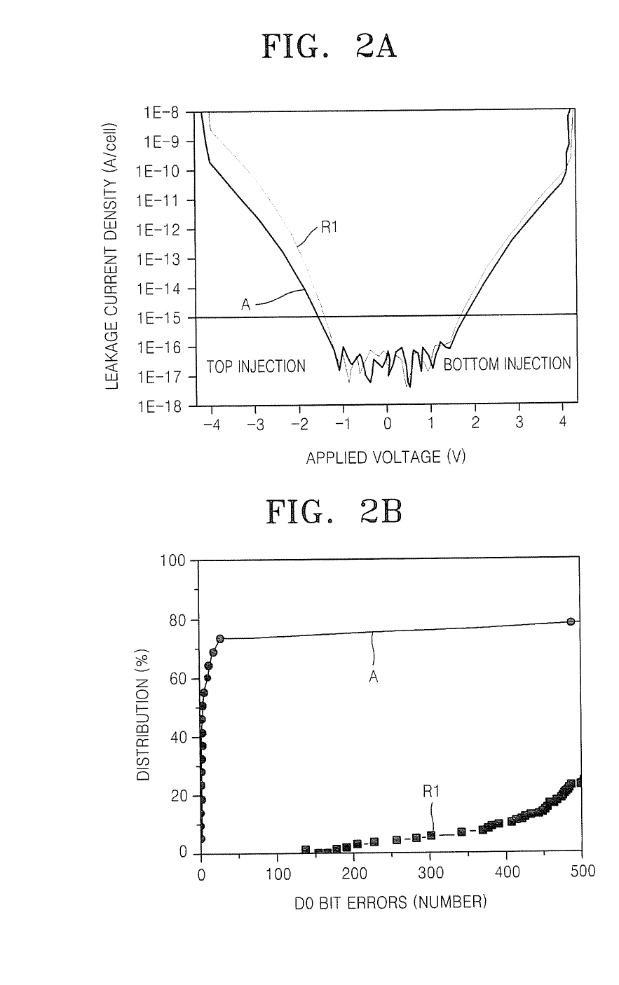

FIGS. 2A and 2B are graphs showing leakage current and percentage of bit error of capacitor including a multi-layer dielectric structure of ZrₓSi_{y}O_{z}/AlOₓ 120a as illustrated in FIG. 1 and capacitor including only a dielectric layer of ZrₓSi_{y}O_{z} for the comparison with the multi-layer dielectric structure of ZrₓSi_{y}O_{z}/AlOₓ. In FIG. 2, a curve A represents analysis of a capacitor including a multi-layer dielectric structure including ZrₓSi_{y}O_{z} (70 Å) and AlOₓ (4 Å), and a curve R1 represents analysis of a capacitor including only a dielectric layer of ZrₓSi_{y}O_{z} (90 Å). The First and second electrodes are formed of a titanium nitride.

In order to emulate the back-end process, the capacitors were analyzed after being heat-treat at 550° C. for 2 minutes. The analysis of Bit error on the capacitors was conducted by a D0 test involving writing a bit data value “0” to the capacitors.

Referring to FIG. 2A, it is found that a leakage current (curve A) of the capacitor having the multi-layer dielectric structure of ZrₓSi_{y}O_{z}/AlOₓ according to an example embodiment of the present invention is lower than a leakage current (curve R1) of the capacitor including a dielectric layer of ZrₓSi_{y}O_{z}, so that the multi-layer dielectric structure of ZrₓSi_{y}O_{z}/AlOₓ has better leakage current characteristics than the dielectric layer of ZrₓSi_{y}O_{z}. In particular, in a top injection mode of the capacitor having the multi-layer dielectric structure of ZrₓSi_{y}O_{z}/AlOₓ, the leakage current is significantly reduced.

Referring to FIG. 2B, there are almost no bit errors in the capacitor (curve A) having the multi-layer dielectric structure of ZrₓSi_{y}O_{z}/AlOₓ, after the D0 test. However, in the capacitor (curve R1) including only a dielectric layer of ZrₓSi_{y}O_{z}, there are 500 or more bit errors which reach to 20% or greater of total capacitors. In other word, the capacitor having the multi-layer dielectric structure of ZrₓSi_{y}O_{z}/AlOₓ has quite better reliability than the capacitor having only the dielectric layer of ZrₓSi_{y}O_{z} in view of the bit errors.

It can be clearly understood from the result shown in FIGS. 2A and 2B that excessive grain growth in the first dielectric layer 112 which may occur during a back-end process after forming the capacitor 10 can be effectively prevented or reduced by the second dielectric layer 114 that has a higher crystallization temperature than that of the first dielectric layer 112. That is, considering that grain boundaries of the first dielectric layer is the main path of leakage current, the second dielectric layer prevents or reduces the excessive grain growth of the first dielectric layer 112 during the high temperature back-end process, resulting decrease in the leakage current and fail bits of the first dielectric layer 112.

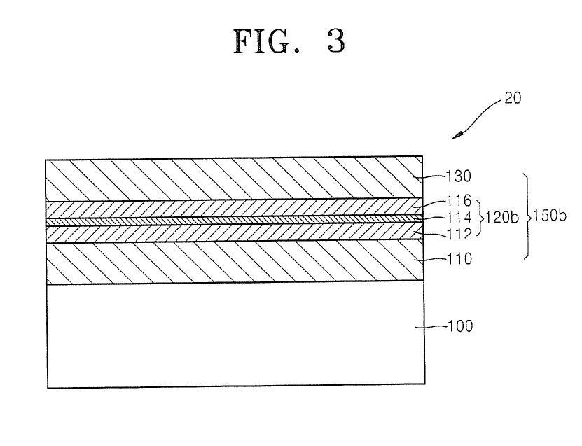

FIG. 3 is a cross-sectional view of a semiconductor device 20 including a multi-layer dielectric structure 120b according to another example embodiment of the present invention. Description about the elements indicated by the same numerical references like in FIG. 1 will not be repeated here and such elements can be referred to the corresponding description with reference to FIG. 1.

Referring to FIG. 3, a multi-layer dielectric structure 120b in the semiconductor device 20 may further include a third dielectric layer 116 disposed between a second electrode 130 and the second dielectric layer 114 as well as the first and second dielectric layers 112 and 114. As the first dielectric layer 112 includes a first high-k dielectric layer, the third dielectric layer 116 may include a second high-k dielectric layer. The second high-k dielectric layer may include a zirconium oxide layer (ZrOₓ), a hafnium oxide layer (HfOₓ), a lanthanum oxide layer (LaOₓ), a tantalum oxide layer (TaOₓ) or a combination thereof. In an example embodiment, the third dielectric layer 116 may be doped with nitrogen, and may be, for example, a zirconium oxynitride layer (ZrON), a hafnium oxynitride layer (HfON), a lanthanum oxynitride layer (LaON), a tantalum oxynitride layer (TaON) or a combination thereof. The nitrogen contained in the second high-k dielectric layer may increase dielectric constant as well as chemical and thermal stability of the third dielectric layer 116, which is disclosed in U.S. Patent Publication No. 2006/0046380.

The compositions of the first and second high-k dielectric layers may be the same or different with each other. In addition, the third dielectric layer 116 may also include silicon doped in the second high-k dielectric layer as the first dielectric layer 112. In an example embodiment, for a case where a capacitor 150b is operated in a top injection mode, the thickness of the third dielectric layer 116 disposed adjacent to the second electrode 130 may be equal to or less than that of the first dielectric layer 112.

The first through third dielectric layers 112, 114, and 116 of the capacitor 150b may be formed by CVD or ALD. These dielectric layers 112, 114, and 116 may preferably be formed by ALD by which these layers can be formed in unit of molecular layer on a substrate 100 due to the nature of the self-saturating chemical reaction as described above.

Although not illustrated in FIG. 3, an access device for driving the capacitor 150b may be disposed on a substrate 100 of the semiconductor device 20. The first and second electrodes 110 and 130 may be a bottom electrode and a top electrode of the capacitor 150b, respectively as illustrated in FIG. 1. A metal having a high work function such as Ru may be used as a conductive layer for the electrodes. However, instead of Ru, the conductive layer for the electrodes may include one selected from the group consisting of titanium, tantalum, tungsten, nitrides thereof, and a combination thereof.

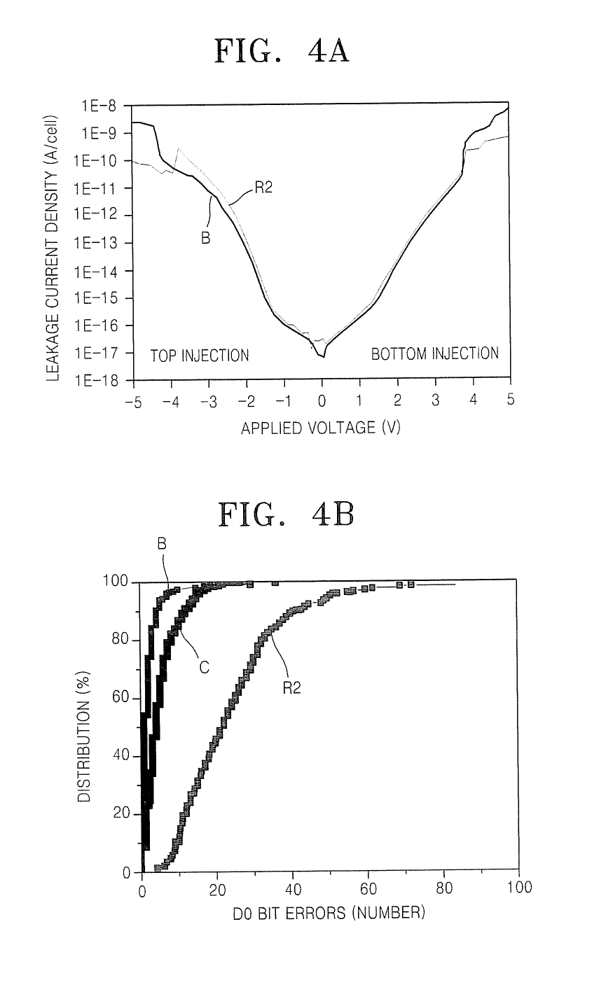

FIGS. 4A and 4B are graphs showing leakage current and percentage of bit error of capacitors 150b including a multi-layer dielectric structure of ZrₓSi_{y}O_{z}/AlOₓ/ZrOₓ according to an example embodiment of the present invention and capacitors including a multi-layer dielectric structure of ZrOₓ/AlOₓ/ZrOₓ for the comparison with the multi-layer dielectric structure of ZrₓSi_{y}O_{z}/AlOₓ/ZrOₓ. In FIGS. 4A and 4B, curves B and C show the behaviors of the two capacitors including the multi-layer dielectric structure of ZrₓSi_{y}O_{z}/AlOₓ/ZrOₓ, and curve R2 shows the behavior of the capacitor including the multi-layer dielectric structure of ZrOₓ/AlOₓ/ZrOₓ. The curve B is corresponded to ZrₓSi_{y}O_{z}/AlOₓ/ZrOₓ where ALD for forming the AlOₓ is conducted three times with a cycle including an Al precursor pulse/oxidizing agent pulse, and the curve C is corresponded to ZrₓSi_{y}O_{z}/AlOₓ/ZrOₓ where ALD for forming the AlOₓ is conducted four times with a cycle including an Al precursor pulse/oxidizing agent pulse. In other word, the ZrₓSi_{y}O_{z}/AlOₓ/ZrOₓ designated by curve B has thicker second dielectric layer of AlOx than the ZrₓSi_{y}O_{z}/AlOₓ/ZrOₓ designated by curve C.

In order to emulate a back-end process, the capacitors were heat-treated at 550° C. for 2 minutes prior to the analysis. Bit error analysis is performed by conducting a D0 test involving writing a bit data value “0” to the capacitors. Also, first and second electrodes were formed of a titanium nitride.

Referring to FIG. 4A, the capacitors (curves B and C) including the multi-layer dielectric structure of ZrₓSi_{y}O_{z}/AlOₓ/ZrOₓ and the capacitor (curve R2) including the multi-layer dielectric structure of ZrOₓ/AlOₓ/ZrOₓ do not have a large difference in leakage current characteristics thereof, but in a negative voltage area, that is, in a top injection mode, the capacitors including the multi-layer dielectric structure of ZrₓSi_{y}O_{z}/AlOₓ/ZrOₓ has slightly better leakage current characteristics than the capacitor including the multi-layer dielectric structure of ZrOₓ/AlOₓ/ZrOₓ.

Referring to FIG. 4B, in the capacitor (curve R2) including the multi-layer dielectric structure of ZrOₓ/AlOx/ZrOx, 20 or more bit errors are generated at about 50%; however in the capacitors (curves B and C) including the multi-layer dielectric structure of ZrₓSi_{y}O_{z}/AlOₓ/ZrOₓ, bit errors rarely occur. The capacitors including the multi-layer dielectric structure of ZrₓSi_{y}O_{z}/AlOₓ/ZrOₓ show significantly better reliability than the capacitor including the multi-layer dielectric structure of ZrOₓ/AlOₓ/ZrOₓ in view of the percentage of bit errors.

Though the above-described embodiments are disclosed in connection with stacked capacitors, the present invention is not limited thereto. For example, it can be easily understood that the semiconductor device may include capacitors having a three-dimensional structure or trench structure.

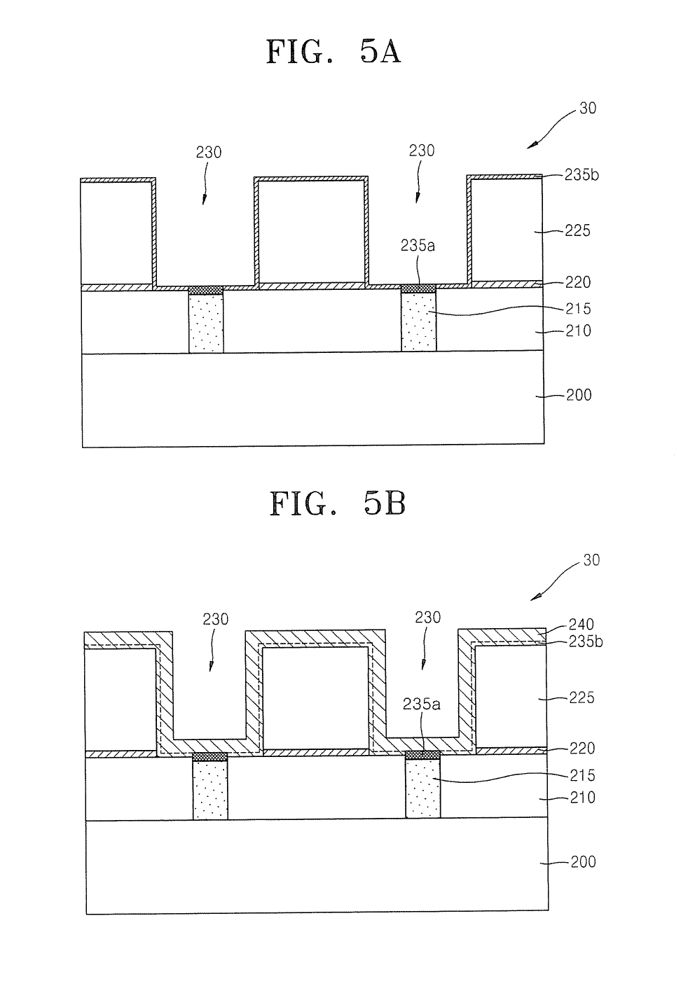

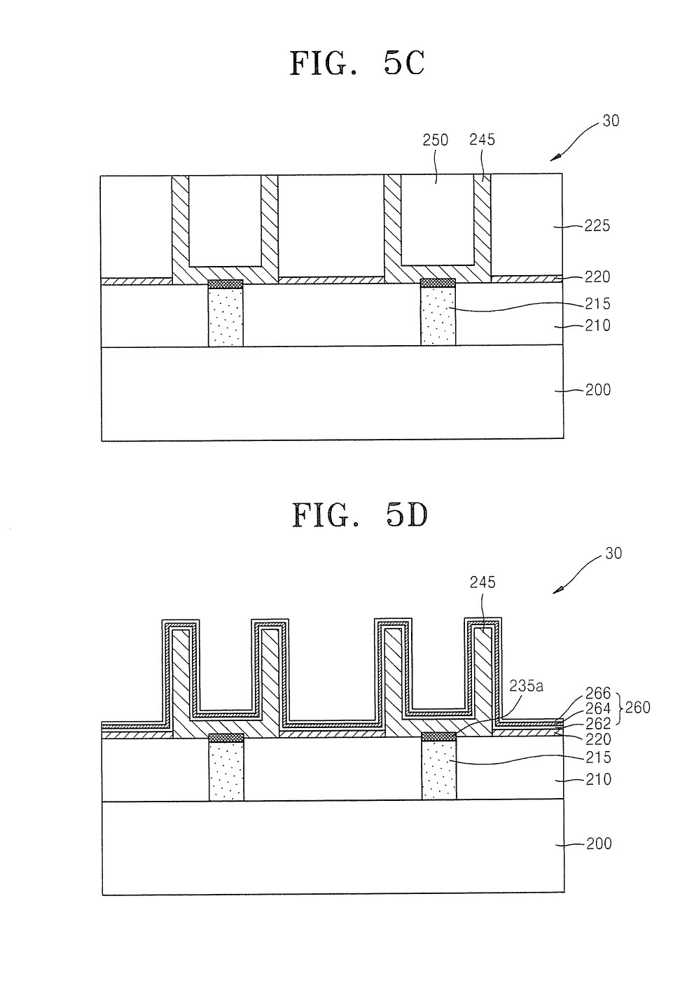

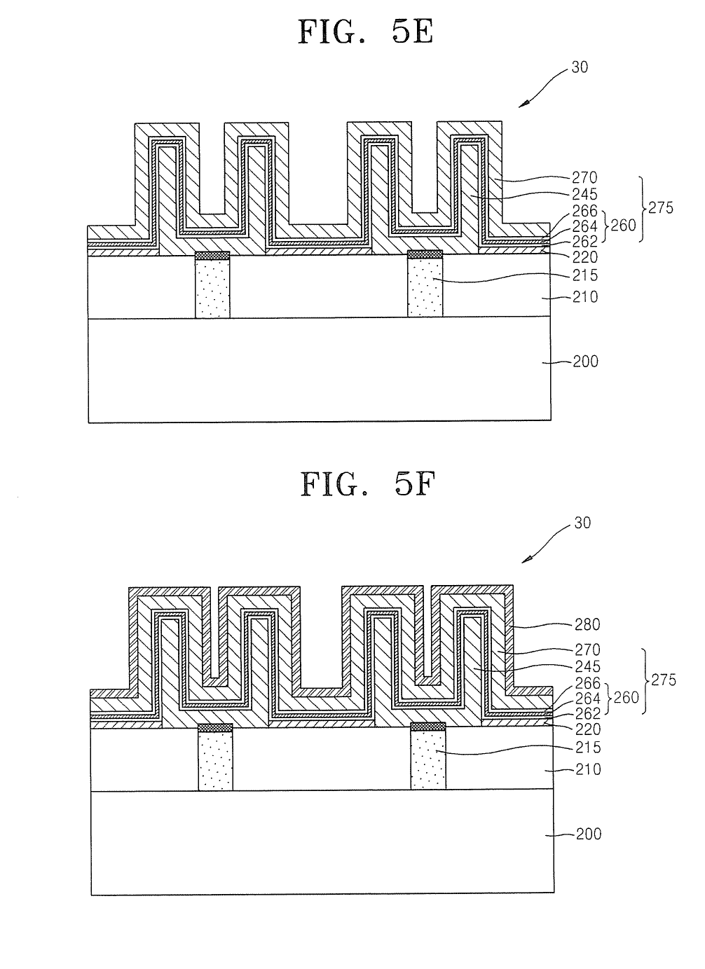

FIGS. 5A through 5F are cross-sectional views illustrating processes of fabricating a semiconductor device 30 according to another example embodiment of the present invention.

Referring to FIG. 5A, an interlayer insulating layer 210 is formed on a substrate 200. A access device (not shown) such as a metal-oxide-semiconductor (MOS) transistor and components electrically connected to the MOS transistor, such as conductive pads, bit line, or the like may be formed between the substrate 200 and the interlayer insulating layer 210. Also, a contact plug 215 may be formed in a predetermined region in the interlayer insulating layer 210 using a well-known method. The contact plug, 215 may be formed of, for example, a doped poly-silicon layer or a titanium nitride layer. The contact plug 215 may be electrically connected to a source (not shown) of the MOS transistor or to a conductive pad (not shown) that is electrically connected to the source.

An etch stopper 220 and a first insulating layer 225 are sequentially formed on the interlayer insulating layer 210 and the contact plug 215. The etch stopper 220 may be a layer, for example, a silicon nitride layer, having an etch selectivity with respect to the first insulating layer 225. The first insulating layer 225 may be a mold oxide layer to define the shape of a capacitor (275 of FIG. 5E). The first insulating layer 225 may determine the height and shape of a bottom electrode in the capacitor 275. The first insulating layer 225 and the etch stopper 220 are etched so as to expose the contact plug 215, thereby defining an opening 230 for forming the capacitor 275.

When the contact plug 215 is a doped polysilicon layer, a layer of transition metal (not shown) such as titanium, tantalum, or tungsten may be formed on surface of the opening 230 and the first insulating layer 225. In an example embodiment, the layer of transition metal may be a titanium metal layer, and may be formed by CVD at a temperature of, for example, about 600 to about 650° C. Also, the layer of transition metal may have a thickness of about 30 to about 90 Å. Then, a silicide layer 235a may be formed on a surface of the contact plug 215 by heat-treating the layer of transition metal. When the heat treatment is conducted in a nitrogen atmosphere, the layer of transition metal may become a nitride, and, thus, a metal nitride layer 235b may remain on the bottom electrode region 230 and the first insulating layer 225.

Referring to FIG. 5B, a metal layer 240 for a bottom electrode, that is, a first electrode 245 (see FIG. 3C), is formed on the opening 230 and the first insulating layer 225. The metal layer 240 may be a metal nitride layer. The metal nitride layer may be, for example, a titanium nitride layer, a tantalum nitride layer, or a tungsten nitride layer. In an example embodiment, the metal nitride layer and the remaining layer of transition metal 235b may be formed of the same material. The metal nitride layer may be formed by PVD. CVD. ALD, or SFD as described above.

For example, the metal layer 240, for example, a titanium nitride layer for forming a bottom electrode may be formed by performing an ALD including a titanium precursor source (e.g., titanium chloride (TiCl₄)) and a nitrogen precursor gas (e.g. ammonia (NH₃)) in a reactor for a predetermined time. The ALD for forming the titanium nitride layer may include a titanium chloride pulse/purge/an ammonia pulse/purge.

Alternatively, as disclosed in U.S. Patent Publication No. 2006/0046380, the titanium nitride layer may be formed by the SFD which may include supplying ammonia, supplying ammonia and a titanium chloride simultaneously while ammonia is supplied for a predetermined time, and stopping supplying the titanium chloride to supply ammonia for a predetermined time. In the SFD, the ammonia may be supplied for a predetermined time before supplying a titanium chloride source, and, thus, an atmosphere, in which chlorine of the titanium chloride does not penetrate to the lower portions of the semiconductor device 30, for example, toward the interlayer insulating layer 210 and the contact plug 215, can be obtained. Also, after completing the supplying of the titanium chloride, only ammonia may be supplied for a predetermined time to remove chlorine that is generated when supplying the titanium chloride (H+Cl→HCl↑). The metal layer 240 such as a titanium nitride layer may be formed at a temperature of about 300 to about 600° C. and at a pressure of about 1 through about 10 Torr, preferably at about 2 through about 3 Torr.

As is well known in the art, a metal source for forming a metal nitride layer usually includes a chlorine group, and the chlorine group may penetrate into the interlayer insulating layer 210 and the contact plug 215 or cause stress, defects, or cracks in the metal nitride layer. Also, the chlorine group may deteriorate interface characteristics between the metal nitride layer and the etch stopper 220. However, the SFD may address these problems caused from the chlorine group by supplying a source that can remove the chlorine before or after supplying a metal source including the chlorine group for forming the metal layer 240.

Referring to FIG. 5C, a second insulating layer 250 may be formed on the metal layer 240. The second insulating layer 250 is a sacrificial layer, and may be, for example, a silicon oxide layer. Then, the second insulating layer 250 and the metal layer 240 are planarized until surfaces of the first insulating layer 225 is exposed, thereby forming the bottom electrode 245. The planarization may be performed by chemical mechanical polishing (CMP) or etch back process.

As illustrated in FIG. 5D, the first and second insulating layers 225 and 250 may be removed using, for example, wet etch. Then a first dielectric layer 262 including a first high-k dielectric layer doped with silicon may be formed on surfaces of the etch stopper 220 and the bottom electrode 245.

The first dielectric layer 262 may have a thickness of about 1 to about 10 nm for a DRAM device having a design rule of 100 nm or less, and may be formed by ALD. Though the bottom electrode of the capacitor has a large aspect ratio due to narrow design rule, the first dielectric layer 262 may be conformally formed on the metal layer 240 by the self-restrictive nature of the ALD.

In an example embodiment, a pumping down may be performed prior to each precursor pulse in order to improve step coverage characteristics of the first dielectric layer 262, which is disclosed in U.S. Patent Publication No. 2006/0046380.

For example, an inert gas such as Ar, which is supplied into the reactor during a purge step, removes excess reactants or reaction byproducts which are not chemically adsorbed on the resulting structure. However, when the inert gas is not completely removed but remains on the resulting structure, a silicon precursor or a metal precursor to be subsequently supplied may not be uniformly adhered to a surface of the resulting structure. Thus, when the pumping down for removing a purging gas or residue is performed according to an example embodiment of the present invention, reactants generated by the pulses may be uniformly, chemically adsorbed to the surface of the resulting structure, thereby improving step coverage characteristics of the first dielectric layer 262. In this case, each step in one cycle may be performed for a time period within a range of about 0.1 to about 10 seconds, and it is preferable that one cycle is performed within 20 seconds. In addition, as described above, the pumping down may be performed prior to supplying the reaction sources. However, in consideration of throughput, the pumping down may also be performed only at the beginning or end of the cycle.

A second dielectric layer 264 having a higher crystallization temperature than that of the first dielectric layer 262 may be formed on the first dielectric layer 262. The second dielectric layer 264 may have a greater thickness than that of the first dielectric layer 262, for example, about 1 through about 20 Å. The second dielectric layer 264 may also be formed by ALD similarly to the first dielectric layer 262.

When forming the second dielectric layer 264 by ALD, a cycle for forming the second dielectric layer 264 may include a metal precursor pulse/purge/oxidizing agent pulse/purge. Similarly to the first dielectric layer 262, a pumping down may be performed prior to each metal precursor pulse when forming the second dielectric layer 264. For example, in order to form an aluminum oxide layer to be the second dielectric layer 264, a pumping down may be performed prior to each aluminum precursor pulse, thereby removing residual impurities on the surface of the underlying first dielectric layer 262.

Then, an aluminum precursor pulse may be applied and a purging step may be performed to remove excess reactants and/or reaction byproducts. After the purge step, in order to removing a purge gas, for example, Ar that may remain on a surface of the resulting structure, a pumping down may be performed again. Then, an oxidizing agent pulse such as an ozone (O₃) pulse may be supplied to form a monolayer of aluminum oxide on a surface of the resulting structure. In an example embodiment, an oxidizing agent pulse and a purge step may be conducted for a longer period of time than the metal precursor pulse. As described above, when the oxidizing agent pulse and the purge step are elongated, metal from the metal precursor pulse and oxygen from the oxidizing agent pulse can be effectively transported to a bottom of the lower electrode 245, thereby further improving the step coverage characteristics of the second dielectric layer 264.

A multi-layer dielectric structure 260 may be completed by forming a third dielectric layer 266 on the second dielectric layer 264. The third dielectric layer 266 may have a thickness of about 1 through 10 nm, and the third dielectric layer 266 may include a second high-k dielectric layer. The second high-k dielectric layer may include a zirconium oxide, a hafnium oxide, a lanthanum oxide, a tantalum oxide or a combination thereof. For the injection mode of the capacitor, the thickness of the third dielectric layer 266 may be equal to or less than that of the first dielectric layer 262.

Next, a post treatment may be performed on the multi-layer dielectric structure 260. For example, the post treatment may be a plasma treatment. The plasma may be direct plasma, remote plasma, or modified magnetron type (MMT) plasma. Also, the plasma treatment may be performed at a substrate temperature of about 150 to 400° C., preferably at a substrate temperature of about 250° C. Also, the plasma treatment may be performed at a pressure of several Torr, for example, about 1.5 Torr, and for about 3 to about 8 minutes.

In an example embodiment, the plasma treatment may be performed in an atmosphere of oxygen (O₂), nitrogen (N₂), ammonia (NH₃), hydrogen (H₂), or nitric acid (N₂O). When the plasma treatment is performed in an oxygen atmosphere, the oxygen may be supplied into the multi-layer dielectric structure 260 and thus deterioration of electrical properties such as the leakage current of the multi-layer dielectric structure 260, which may be caused by oxygen deficiency, may be prevented or reduced.

Referring to FIG. 5E, a second electrode 270, that is, a top electrode, may be formed on the multi-layer dielectric structure 260, thereby completing a capacitor 275. For example, the second electrode 270 may include a metal nitride layer. The second electrode 270 may be formed of the same material as that of the first electrode 245 or may be formed by using the same process.

Referring to FIG. 5F, a capping layer 280 may be formed on the second electrode 270. The capping layer 280 may improve adhesion between the second electrode 270 and an insulating layer (not shown) to be subsequently formed. The capping layer 280 may include silicon germanium (SiGe), polysilicon, or tungsten (W). The silicon germanium is preferable, because the silicon germanium may be formed at a temperature lower than polysilicon, for example, 450° C. or lower and, thus, thermal stress applied to the underlying capacitor 275 during the formation of the capping layer 280 may be reduced.

In the above described embodiments, a stacked capacitor and a cylinder capacitor are disclosed, but the present invention is not limited thereto. For example, the multi-layer dielectric structure of the present invention may also be applied to a trench type capacitor. The semiconductor device including the multi-layer dielectric structure may be applied to a DRAM or an embedded DRAM (eDRAM) device.

The present invention also includes other embodiments as described below as well as the above-described embodiments.

1) A method of fabricating a semiconductor device, the method comprising:

providing a substrate in a reactor;

forming a first conductive layer to be a first electrode, on the substrate;

forming at least one first dielectric layer including a first high-k dielectric layer doped with silicon, on the conductive layer to be a first electrode;

forming at least one second dielectric layer having a higher crystallization temperature than that of the first dielectric layer, on the first dielectric layer; and

forming a second conductive layer to be a second electrode, on the second dielectric layer.

2) The method of above 1) item, wherein the forming of the at least one first dielectric layer is performed by chemical vapor deposition (CVD) or atomic layer deposition (ALD).

3) The method of above 2) item, wherein the ALD is conducted by performing, at least once, a cycle including a silicon precursor pulse/oxidizing agent pulse/metal precursor pulse/oxidizing agent pulse or including a metal precursor pulse/oxidizing agent pulse silicon precursor pulse/oxidizing agent pulse.

4) The method of above 2) item, wherein the ALD is conducted by performing, at least once, an ALD cycle including a silicon precursor pulse/metal precursor pulse/oxidizing agent pulse or including an oxidizing agent pulse/silicon precursor pulse/metal precursor pulse.

5) The method of above 1) item, wherein at least one of the first and second conductive layers comprises at least one of the group consisting of a titanium nitride layer, a tantalum nitride layer, and a tungsten nitride layer.

6) The method of above 1) item, wherein the first high-k dielectric layer comprises one of the group consisting of a zirconium oxide layer (ZrOₓ), a hafnium oxide layer (HfOₓ), a lanthanum oxide layer (LaOₓ), and a combination thereof.

7) The method of above 1) item, wherein the second dielectric layer comprises one of the group consisting of an aluminum oxide layer (AlOₓ), an aluminum nitride layer (AlNₓ) and a combination thereof.

8) The method of above 1) item, prior to the forming of the second conductive layer, further comprising forming a third dielectric layer including a second high-k dielectric layer on the second dielectric layer.

9) The method of above 8) item, wherein the second high-k dielectric layer comprises one of the group consisting of a zirconium oxide layer (ZrOₓ), a hafnium oxide layer (HfOₓ), a lanthanum oxide layer (LaOₓ), and a combination thereof.

Also, it will be understood by one of ordinary skill in the art that the multi layer dielectric structure including the first and second dielectric layer and/or the multi layer dielectric structure including the first, second and third dielectric layers may be modified to be repeated at least twice between the first and second electrodes. Also, the features of at least one embodiment of the present invention may be combined with at least one feature of other embodiments of the present invention, without departing from the scope of the inventive concept.

While the present invention has been particularly shown and described with reference to exemplary embodiments thereof, it will be understood that various changes in form and details may be made therein without departing from the spirit and scope of the following claims.

What is claimed is:

1. A semiconductor device comprising a capacitor, the capacitor comprising:
first and second electrodes facing each other;
at least one first dielectric layer that is disposed between the first and second electrodes, the at least one first dielectric layer comprising a first high-k dielectric layer doped with silicon; and
at least one second dielectric layer that is disposed between the at least one first dielectric layer and any of the first and second electrodes, the at least one second dielectric layer having a higher crystallization temperature than that of the first dielectric layer.

2. The semiconductor device of claim 1, wherein at least one of the first and second electrodes comprises at least one of the group consisting of a titanium nitride layer, a tantalum nitride layer, and a tungsten nitride layer.

3. The semiconductor device of claim 1, wherein the first and second electrodes are a bottom electrode and a top electrode of the capacitor, respectively, and
the at least one second dielectric layer is disposed between the at least one first dielectric layer and the second electrode.

4. The semiconductor device of claim 1, wherein the first high-k dielectric layer comprises one selected from the group consisting of a zirconium oxide layer (ZrOₓ), a hafnium oxide layer (HfOₓ), a lanthanum oxide layer (LaOₓ), and a combination thereof.

5. The semiconductor device of claim 1, wherein the at least one second dielectric layer comprises one selected from the group consisting of an aluminum oxide layer (AlOₓ), an aluminum nitride layer (AlNₓ), and a combination thereof.

6. The semiconductor device of claim 1, further comprising at least one third dielectric layer disposed between the at least one second dielectric layer and the other of the first and second electrodes,
wherein the at least one third dielectric layer comprises a second high-k dielectric layer.

7. The semiconductor device of claim 6, wherein the second high-k dielectric layer comprises one selected from the group consisting of a zirconium oxide layer (ZrOₓ), a hafnium oxide layer (HfOₓ), a lanthanum oxide layer (LaOₓ), and a combination thereof.

8. The semiconductor device of claim 6, wherein the second high-k dielectric layer is doped with silicon.

9. The semiconductor device of claim 6, wherein the first and second electrodes are a bottom electrode and a top electrode of the capacitor, respectively, and
the at least one second dielectric layer is disposed between the at least one first dielectric layer and the second electrode, and the at least one third dielectric layer is disposed between the at least one second dielectric layer and the second electrode, and
the thickness of the at least one first dielectric layer is greater than that of the at least one third dielectric layer.

10. The semiconductor device of claim 1, wherein the thickness of the at least one second dielectric layer is less than that of the at least one first dielectric layer.

11. The semiconductor device of claim 1, wherein the thickness of the at least one second dielectric layer is 1 to 20 Å.

12. The semiconductor device of claim 1, wherein the thickness of the at least one first dielectric layer is 40 to 100 Å.

13. The semiconductor device of claim 1, wherein the capacitor is a stacked capacitor, a cylinder capacitor, or a trench capacitor.

14. An integrated circuit capacitor, comprising:
first and second capacitor electrodes on a substrate;
a first dielectric layer comprising a silicon-doped metal oxide extending between said first and second capacitor electrodes; and
a second dielectric layer extending between said first dielectric layer and said first capacitor electrode, said second dielectric layer having a higher crystallization temperature relative to said first dielectric layer.

15. The capacitor of claim 14, wherein said first dielectric layer comprises a material selected from a group consisting of ZrₓSi_{y}O_{z}, HfₓSi_{y}O_{z}, LaₓSi_{y}O_{z} and TaₓSi_{y}O_{z}, where x>0, y>0 and z>0 and x+y=1.

16. The capacitor of claim 15, wherein said first capacitor electrode comprises a material selected from a group consisting of titanium nitride, tantalum nitride and tungsten nitride.

17. The capacitor of claim 14, wherein said first capacitor electrode comprises a material selected from a group consisting of titanium nitride, tantalum nitride and tungsten nitride.

18. The capacitor of claim 15, wherein said second dielectric layer comprises a material selected from a group consisting of aluminum oxide and aluminum nitride.

19. The capacitor of claim 14, further comprising a third dielectric layer comprising a silicon-doped metal oxide extending between said second dielectric layer and said first capacitor electrode.

20. The capacitor of claim 15, further comprising a third dielectric layer comprising a silicon-doped metal oxide extending between said second dielectric layer and said first capacitor electrode.
